(19) United States
(12) Patent Application Publication
(10) Pub. No.: US 2024/0321901 A1
(43) Pub. Date: Sep. 26, 2024

(54) DISPLAY DEVICE

(71) Applicant: E Ink Holdings Inc., HSINCHU (TW)

(72) Inventors: Hsien-Kai TSENG, HSINCHU (TW); Wei-Chen TSAI, HSINCHU (TW); Jia-Hung CHEN, HSINCHU (TW); Pei-Ju WU, HSINCHU (TW)

(21) Appl. No.: 18/599,227

(22) Filed: Mar. 8, 2024

Related U.S. Application Data
(60) Provisional application No. 63/491,734, filed on Mar. 22, 2023.

(51) Int. Cl. H01L 27/12

(52) U.S. Cl. CPC H01L 27/124

(57) ABSTRACT

A display device includes an array substrate and a driving circuit. The array substrate includes active elements, a first scan line, a second scan line, a third scan line disposed between the first scan line and the second scan line, and a first selection line electrically connected to the first scan line and the second scan line. The active elements include a first active element and a second active element electrically connected to the first scan line, and a third active element and a fourth active element electrically connected to the second scan line. The driving circuit provides a first scan signal transmitted to the first scan line and the second scan line through the first selection line to control the first active element, the second active element, the third active element and the fourth active element.

### RELATED APPLICATIONS

This application claims priority to U.S. Provisional Ser. No. 63/491,734, filed Mar. 22, 2023, which is herein incorporated by reference in its entirety.

### BACKGROUND

### Field of Invention

The present disclosure relates to a display device. More particularly, the present disclosure relates to a display device including a selection line that can simultaneously control at least four active elements.

### Description of Related Art

Display devices have been widely used in various forms of electronic products. In one type of display device, the array substrate includes scan lines, data lines intersecting with the scan lines, and pixel electrodes electrically connected to the data lines. However, when a large number of scan lines must be placed in response to application requirements, such as in the case of a long strip-shaped display device, problems such as increased bezel width, the need to develop chip with special specification, and short pixel charging time resulting in insufficient charging rate and high power consumption may occur.

### SUMMARY

At least one embodiment of the present disclosure provides an array substrate, which includes a selection line that can simultaneously control at least four active elements so that the pixels have a sufficient charging rate and can reduce power consumption. In addition, it may be applied to products with narrow bezels or products using established specification chips, depending on product requirements.

Another embodiment of the present disclosure provides a display device, which includes the abovementioned array substrate.

The display device according to at least one embodiment of the present disclosure includes an array substrate and a driving circuit. The array substrate includes a substrate, scan lines, data lines, selection lines, and active elements. The scan lines are disposed on the substrate and include a first scan line, a second scan line and a third scan line, where the third scan line is disposed between the first scan line and the second scan line. The data lines are disposed on the substrate and electrically insulated from the scan lines. The selection lines are disposed on the substrate, intersect with the scan lines and are electrically insulated from the data lines, where the selection lines include a first selection line, and the first selection line is electrically connected to the first scan line and the second scan line. The active elements include a first active element, a second active element, a third active element and a fourth active element, where the first active element and the second active element are electrically connected to the first scan line, and the third active element and the fourth active element are electrically connected to the second scan line. The driving circuit provides data signals to the data lines and scan signals to the selection lines. The scan signals include a first scan signal transmitted to the first scan line and the second scan line through the first selection line to control the first active element, the second active element, the third active element and the fourth active element.

The array substrate according to at least one embodiment of the present disclosure includes a substrate, scan lines, data lines, selection lines, and active elements. The scan lines are disposed on the substrate and include a first scan line, a second scan line and a third scan line, where the third scan line is disposed between the first scan line and the second scan line. The data lines are disposed on the substrate and electrically insulated from the scan lines. The selection lines are disposed on the substrate, intersect with the scan lines and are electrically insulated from the data lines, where the selection lines include a first selection line, and the first selection line is electrically connected to the first scan line and the second scan line. The active elements include a first active element, a second active element, a third active element and a fourth active element, where the first active element and the second active element are electrically connected to the first scan line, and the third active element and the fourth active element are electrically connected to the second scan line. The data lines receive data signals and the selection lines receive scan signals, where the scan signals include a first scan signal transmitted to the first scan line and the second scan line through the first selection line to control the first active element, the second active element, the third active element and the fourth active element.

It is to be understood that both the foregoing general description and the following detailed description are by examples, and are intended to provide further explanation of the present disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic top view of a display device according to at least one embodiment of the present disclosure.

FIG. 2 is a schematic top view of a display device according to at least another embodiment of the present disclosure.

FIG. 3 is an enlarged schematic view of region A in FIG. 2.

FIG. 4 is a schematic cross-sectional view taken along line a-a′ of FIG. 3.

FIG. 5 is an enlarged schematic view of a display device according to at least another embodiment of the present disclosure.

FIG. 6 is a schematic cross-sectional view taken along line b-b′ of FIG. 5.

### DETAILED DESCRIPTION

The embodiments of the present disclosure are discussed in detail below. It will be appreciated, however, that the embodiments provide many applicable concepts which may be implemented in a wide variety of specific contexts. The discussed and disclosed embodiments are for illustrative purposes only and are not intended to limit the scope of patent applications in this case.

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are “substantially parallel” or “substantially perpendicular,” where “substantially parallel” and “substantially perpendicular,” respectively, mean that parallelism and perpendicularity between the two objects can include non-parallelism and non-perpendicularity caused by permissible deviation ranges.

In addition, “about” may mean within one or more standard deviations of the above values, such as within ±30%, ±20%, ±10%, or ±5%. Such words as “about”, “approximately”, or “substantially” as appearing in the present disclosure may be used to select an acceptable range of deviation or standard deviation according to optical properties, etching properties, mechanical properties, or other properties, rather than applying all of the above optical properties, etching properties, mechanical properties, and other properties with a single standard deviation.

The spatial relative terms used in the present disclosure, such as “below,” “under,” “above,” “on,” and the like, are intended to facilitate the recitation of a relative relationship between one element or feature and another as depicted in the drawings. The true meaning of these spatial relative terms includes other orientations. For example, the relationship between one element and another may change from “below” and “under” to “above” and “on” when the drawing is turned 180 degrees up or down. In addition, spatially relative descriptions used in the present disclosure should be interpreted in the same manner.

It should be understood that while the present disclosure may use terms such as “first”, “second”, “third” to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Moreover, the present disclosure may be implemented or applied in various other specific embodiments, and the details of the present disclosure may be combined, modified, and altered in various embodiments based on different viewpoints and applications, without departing from the idea of the present disclosure.

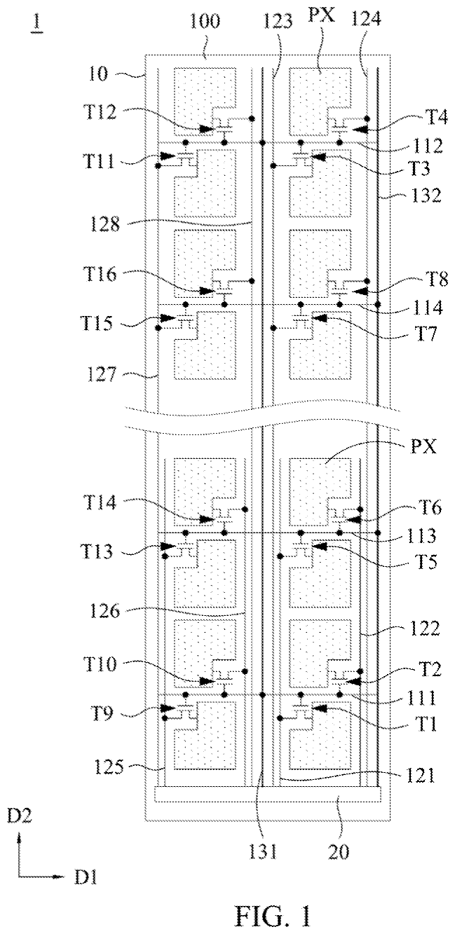

FIG. 1 is a schematic top view of a display device according to at least one embodiment of the present disclosure. The display device 1 includes an array substrate 10 and a driving circuit 20. The array substrate 10 includes a substrate 100, scan lines, data lines, selection lines and active elements. The scan lines are disposed on the substrate 100 and include a first scan line 111, a second scan line 112, and a third scan line 113 disposed between the first scan line 111 and the second scan line 112. The data lines, such as a first data line 121, a second data line 122, a third data line 123 and a fourth data line 124, are disposed on the substrate 100 and are electrically insulated from the scan lines.

As shown in FIG. 1, the selection lines are disposed on the substrate 100 and intersect with the scan lines, and are electrically insulated from the data lines. The selection lines include a first selection line 131 electrically connected to the first scan line 111 and the second scan line 112. The active elements include a first active element T1, a second active element T2, a third active element T3 and a fourth active element T4. The first active element T1 and the second active element T2 are electrically connected to the first scan line 111. The third active element T3 and the fourth active element T4 are electrically connected to the second scan line 112.

The driving circuit 20 provides data signals to the data lines and scan signals to the selection lines. The scan signals include a first scan signal, which is transmitted to the first scan line 111 and the second scan line 112 through the first selection line 131 to control the first active element T1, the second active element T2, the third active element T3 and the fourth active element T4.

Through the connection design of the selection lines, the scanning lines and the active elements, the scan signal provided by the driving circuit to a selection line can be transmitted to at least two scan lines via the selection line to control at least four active elements connected to the at least two scan lines, which allows sufficient charging time for the pixels to have a sufficient charging rate, and reduces the power consumption, as compared to the scan signals provided by the driving circuit to each of the scan lines individually. In addition, since the scan lines receives the scan signal from the driving circuit through the selection lines intersecting the scan lines, even if the number of scan lines is increased to twice the number of existing specification, the bezel width and pins of the existing specification chip do not need to be increased, so it can be applied to products with narrow bezels or products using the existing specification chips.

In some embodiments, the number of selection lines is not greater than half of the number of scan lines, such as the number of selection lines being half of the number of scan lines. In some embodiments, the driving circuit 20 may be disposed in at least one wafer, but is not limited thereto. In FIG. 1, the driving circuit 20 is disposed on the substrate 100, but is not limited thereto. In other embodiments, the driving circuit 20 may be disposed on a circuit board and the circuit board is electrically connected to pads (not shown) disposed on the substrate 100. In some embodiments, the display device 1 further includes a counter substrate (not shown) disposed opposite to the array substrate 10 and a display medium (not shown) disposed between the array substrate 10 and the counter substrate.

In some embodiments, the display medium may be a liquid crystal layer, an electrowetting material layer, an electrophoretic electronic ink, organic light-emitting diodes(OLED), or light-emitting diodes(LED), where the light-emitting diodes may be micro-light-emitting diodes(micro-LED, μLED) or sub-millimeter light-emitting diodes (mini-LED). When the display medium is a liquid crystal layer, the counter substrate may be a color filter substrate, and the substrate 100 may be a light-transmitting substrate. When the display medium is an electrowetting material layer, electrophoretic electronic ink, organic light-emitting diodes, or light-emitting diodes, the counter substrate can be a light-transmitting substrate, and the substrate 100 can be an opaque circuit substrate.

Referring to FIG. 1, the scan lines extend in a first direction D1 and are arranged at intervals in a second direction D2, the data lines extend in the second direction D2 and are arranged at intervals in the first direction D1, and the selection lines extend in the second direction D2 and are arranged at intervals in the first direction D1. The scan lines further include a fourth scan line 114 disposed between the second scan line 112 and the third scan line 113, and the selection lines further include a second selection line 132 electrically connected to the third scan line 113 and the fourth scan line 114. The active elements further include a fifth active element T5 and a sixth active element T6 electrically connected to the third scan line 113, and a seventh active element T7 and an eighth active element T8 electrically connected to the fourth scan line 114. The scan signals further include a second scan signal, where the second scan signal is transmitted to the third scan line 113 and the fourth scan line 114 through the second selection line 132 to control the fifth active element T5, the sixth active element T6, the seventh active element T7 and the eighth active element T8.

The active elements further include a ninth active element T9 and a tenth active element T10 electrically connected to the first scan line 111, an eleventh active element T11 and a twelfth active element T12 electrically connected to the second scan line 112, a thirteenth active element T13 and a fourteenth active element T14 electrically connected to the third scan line 113, and a fifteenth active element T15 and a sixteenth active element T16 electrically connected to the fourth scan line 114. The first scan signal is transmitted to the first scan line 111 and the second scan line 112 through the first selection line 131 to control the ninth active element T9 , the tenth active element T10 , the eleventh active element T11 and the twelfth active element T12, and the second scan signal is transmitted to the third scan line 113 and the fourth scan line 114 through the second selection line 132 to control the thirteenth active element T13, the fourteenth active element T14, the fifteenth active element T15 and the sixteenth active element T16.

The first active element T1 and the fifth active element T5 are electrically connected to the first data line 121, and the second active element T2 and the sixth active element T6 are electrically connected to the second data line 122. The third active element T3 and the seventh active element T7 are electrically connected to the third data line 123, and the fourth active element T4 and the eighth active element T8 are electrically connected to the fourth data line 124. The data lines further include a fifth data line 125, a sixth data line 126, a seventh data line 127 and an eighth data line 128. The ninth active element T9 and the thirteenth active element T13 are electrically connected to the fifth data line 125, and the tenth active element T10 and the fourteenth active element T14 are electrically connected to the sixth data line 126. The eleventh active element T11 and the fifteenth active element T15 are electrically connected to the seventh data line 127, and the twelfth active element T12 and the sixteenth active element T16 are electrically connected to the eighth data line 128.

As shown in FIG. 1, the first data line 121, the second data line 122, the fifth data line 125, and the sixth data line 126 intersect with the first scan line 111 and the third scan line 113, but not with the second scan line 112 and the fourth scan line 114. The third data line 123, the fourth data line 124, the seventh data line 127, and the eighth data line 128 intersect with the first scan line 111, the second scan line 112, the third scan line 113, and the fourth scan line 114. In addition, the display device 1 includes pixel electrodes PX, and the pixel electrodes PX are electrically connected to the active elements, respectively. The pixel electrodes PX are arranged in the second direction D2 to form a pixel column. In the first direction D1, the data line is located between the pixel column and the selection line.

In detail, in the upper half of the display device 1, the third data line 123 and the eighth data line 128 are disposed between the first selection line 131 and the pixel columns on both sides of the first selection line 131, respectively. In the lower half of the display device 1, in addition to the third data line 123 and the eighth data line 128, the first data line 121 and the sixth data line 126 are also disposed between the first selection line 131 and the pixel columns on both sides of the first selection line 131, respectively. Moreover, in the upper half of the display device 1, the fourth data line 124 is disposed between the second selection line 132 and the pixel column, and in the lower half of the display device 1, in addition to the fourth data line 124, the second data line 122 is disposed between the second selection line 132 and the pixel column.

With the abovementioned design, since the data line is arranged between the selection line and the pixel column, the signal of the selection line can be shielded by the data line, so the selection line not be close to the pixel column, and the impact on the surrounding pixel column due to the signal transmitted by the selection line can be reduced, thereby avoiding the problem of uneven display colors.

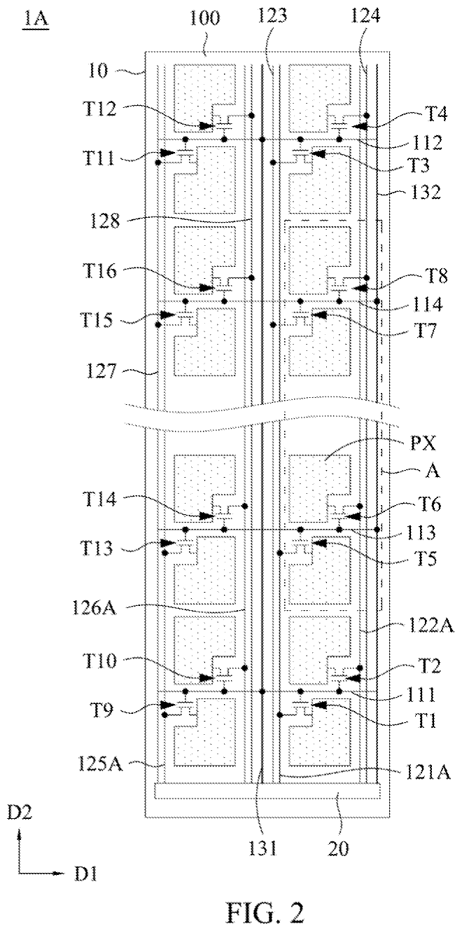

FIG. 2 is a schematic top view of a display device according to at least another embodiment of the present disclosure. The structures and the relative positions of most elements in the embodiments of FIG. 2 and FIG. 1 are the same, so the same features are not repeated here. The difference between the embodiments of FIG. 2 and FIG. 1 is that all data lines of display device 1A intersect with all scan lines. As shown in FIG. 2, the first data line 121A, the second data line 122A, the fifth data line 125A, and the sixth data line 126A intersect the second scan line 112 and the fourth scan line 114, in addition to the first scan line 111 and the third scan line 113. Through the aforementioned design, the capacitive loads of the upper half and the lower half of the display device can be made close to each other, thereby avoiding the problem of uneven display colors caused by the large difference in capacitive loads.

In addition, in other embodiments of the present disclosure, the driving circuit 20 includes a first driving circuit disposed on the upper half of the display device 1 and a second driving circuit disposed on the lower half of the display device 1 (not shown). The first driving circuit is electrically connected to the third data line 123 and the eighth data line 128, where the third data line 123 and the eighth data line 128 are only located on the upper half of the display device 1. The second driving circuit is electrically connected to the first data line 121 and the sixth data line 126, where first data line 121 and the sixth data line 126 are only located on the lower half of the display device 1.

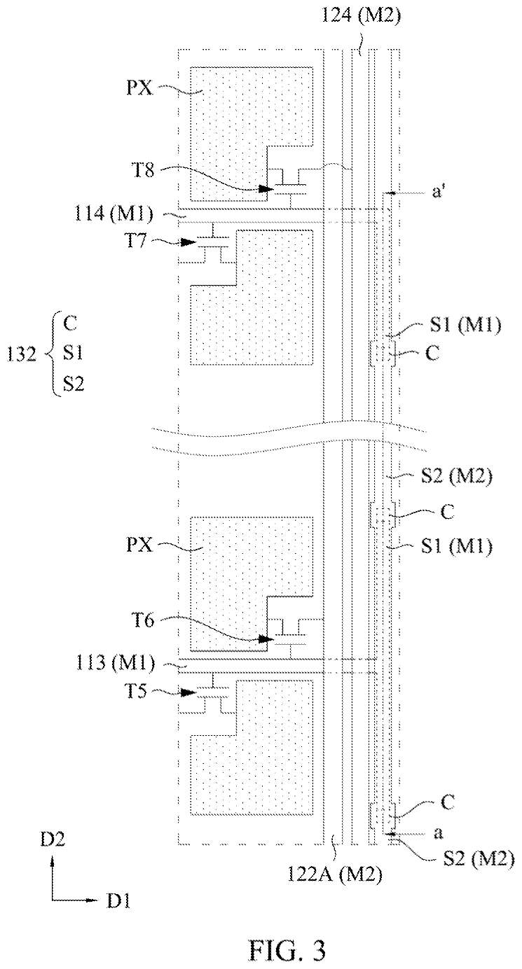

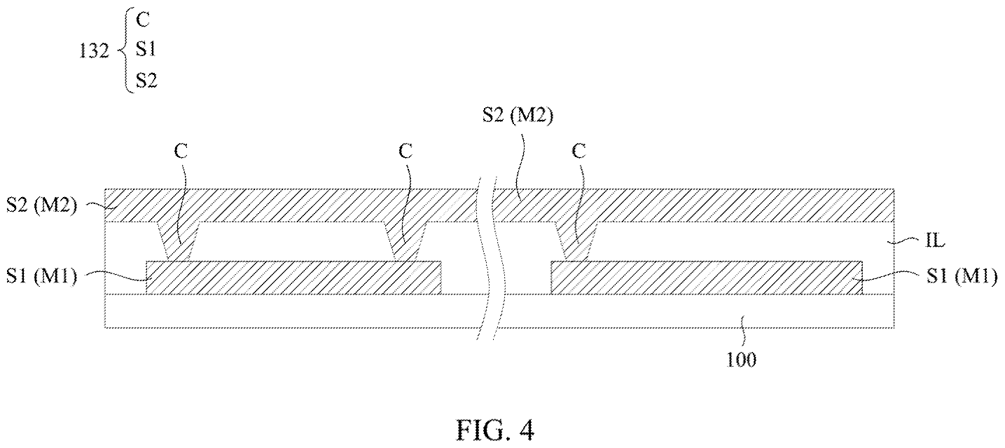

FIG. 3 is an enlarged schematic view of region A in FIG. 2. FIG. 4 is a schematic cross-sectional view taken along line a-a′ of FIG. 3. Referring to FIG. 3 and FIG. 4, the display device 1A includes a first metal pattern layer M1 disposed on the substrate 100, a second metal pattern layer M2 disposed on the first metal pattern layer M1, and an insulating layer IL disposed between the first metal pattern layer M1 and the second metal pattern layer M2. Each of the selection lines includes a first line segment S1, a second line segment S2 and contact parts C. The first metal pattern layer M1 includes the scan lines and the first line segments S1, and the second metal pattern layer M2 includes the data lines and the second line segments S2. In other words, in the normal direction of the substrate 100, the data lines and the second line segments S2 of the selection lines are disposed on the scan lines and the first line segments S1 of the selection lines.

The stacking positions of the above metal pattern layers are not limited to the above embodiment, and the stacking positions of the metal pattern layers can be interchanged, e.g., the first metal pattern layer M1 includes the data lines and the second line segments S2, and the second metal pattern layer M2 includes the scan lines and the first line segments S1. The data lines and the second line segments can also be located in different layers.

Taking FIG. 3 as an example, the second selection line 132 includes the first line segments S1, the second line segments S2 and the contact parts C. The first metal pattern layer M1 includes the third scan line 113, the fourth scan line 114 and the first line segments S1. The second metal pattern layer M2 includes the second data line 122A, the fourth data line 124 and the second line segments S2. In some embodiments, the first line segments S1 and the second line segments S2 extend in the second direction D2.

The second line segments S2 of each selection line pass through the insulating layer IL at the contact parts C of each selection line to electrically connect to the first line segments S1 of each selection line, and the contact parts C of each selection line are not located at intersections of the selection line and the scan lines. Taking FIG. 3 and FIG. 4 as an example. As shown in FIG. 4, the second line segment S2 of the second selection line 132 is electrically connected to the first line segments S1 of the second selection line 132 at the contact parts C of the second selection line 132 passing through the insulating layer IL. As shown in FIG. 3, the contact parts C of the second selection line 132 is not located at the intersections which the second selection line 132 intersects with the third scan line 113 and the fourth scan line 114.

In some embodiments, the number of contact parts C of each selection line is at least three. In some embodiments, the second line segment S2 of each selection line contacts the first line segments S1 of each selection line at the contact parts C of each selection line passing through the insulating layer IL. In some embodiments, each selection line may include a second line segment S2 that is not electrically connected to the first line segment S1 (not shown), and the second line segment S2 may be electrically connected to a common voltage.

By the abovementioned design, the selection line can cross the scan line that is not connected to it by using the second line segment of the second metal pattern layer, and then transfer to the first line segment of the first metal pattern layer at the contact part to connect to the corresponding scan line, and avoid causing signal crosstalk that affects the display quality by not disposing the contact part at the intersection of the selection line and the scan line.

In some embodiments, the material of the substrate 100 may include quartz, glass, polymer material, or other suitable materials. In some embodiments, a deposition process, an inkjet process, a printing process, a coating process, a photolithography etching process, and/or other appropriate processes may be used to form the first metal pattern layer M1, the second metal pattern layer M2, the insulating layer IL and the pixel electrodes PX on the substrate 100.

In some embodiments, the first metal pattern layer M1 and the second metal pattern layer M2 may include metals with good conductivity, such as aluminum, molybdenum, titanium, copper and other metals. The first metal pattern layer M1 includes the scan lines and the first line segments S1 of the selection lines, and the second metal pattern layer M2 includes the data lines and the second line segments S2 of the selection lines. That is, the scan lines and the first line segments S1 of the selection lines are made of the same material and are formed by the same process, and the data lines and the second line segments S2 of the selection lines are made of the same material and are formed by the same process. In other words, the distance between the scan lines and the surface of the substrate 100 is substantially equal to the distance between the first line segments S1 of the selection lines and the surface of the substrate 100, and the distance between the data lines and the surface of the substrate 100 is substantially equal to the second line segments S2 of the selection lines and the surface of the substrate 100.

In some embodiments, the insulating layer IL can be a single-layer structure or a multi-layer stack structure, and the material of the insulating layer IL may include inorganic insulating material, organic insulating material, or combinations thereof. The inorganic insulating material can be, for example, silicon oxide, silicon nitride, silicon oxynitride, etc., and the organic insulating material can be, for example, polymethylmethacrylate, siloxane, polyimide, epoxy, etc. In some embodiments, the material of the pixel electrodes PX may include an opaque conductive material, a transparent conductive material, or a combination thereof. The opaque conductive material can be, for example, molybdenum, molybdenum nitride, molybdenum niobium, etc., and the transparent conductive material can be, for example, Indium tin oxide, indium zinc oxide, etc.

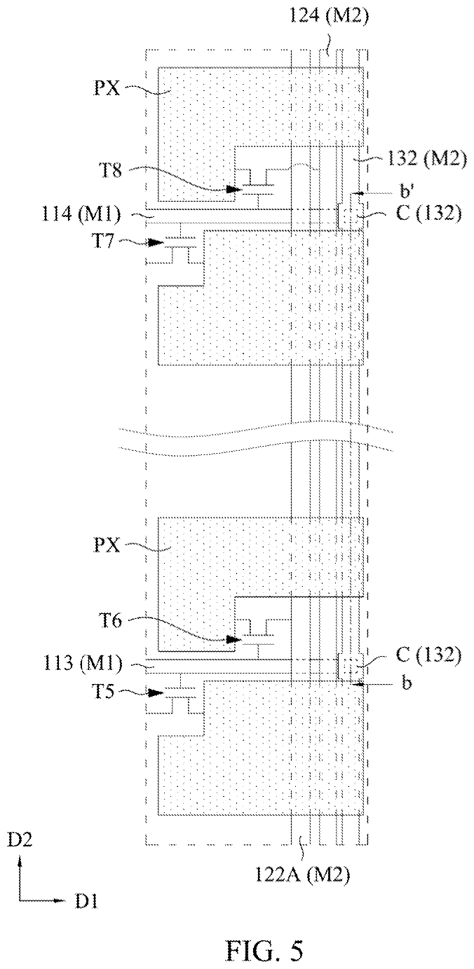

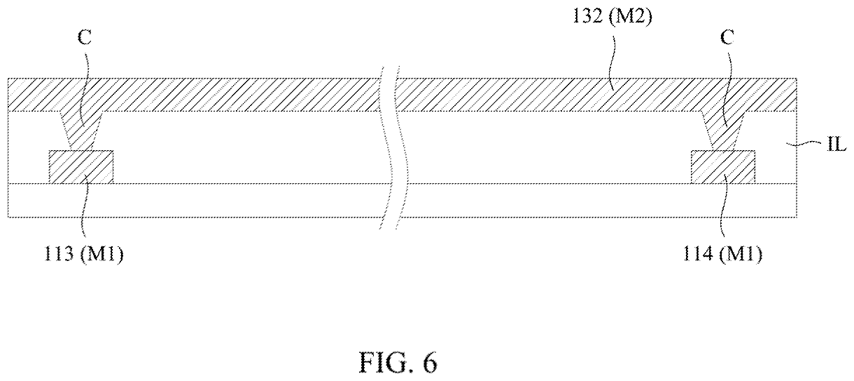

FIG. 5 is an enlarged schematic view of a display device according to at least another embodiment of the present disclosure. FIG. 6 is a schematic cross-sectional view taken along line b-b′ of FIG. 5. The structures, the materials, the manufacturing processes and the relative positions of most elements in the embodiment of FIGS. 5 and 6 and the embodiment of FIGS. 3 and 4 are the same, and the top view of the display device of FIG. 5 is substantially the same as the top view of the display device 1A of FIG. 2, so the same features are not repeated here. The differences between the embodiment of FIGS. 5 and 6 and the embodiment of FIGS. 3 and 4 will be described in detail below.

The pixel electrodes PX may be disposed on the data lines and the selection lines, i.e., the orthographic projections of the pixel electrodes PX on the substrate 100 overlap with the orthographic projections of the data lines and the selection lines on the substrate 100. As shown in FIG. 5, the pixel electrodes PX are disposed on the second data line 122A, the fourth data line 124 and the second selection line 132. That is, the orthographic projections of the pixel electrodes PX on the array substrate 10 overlap with the orthographic projections of the second data line 122A, the fourth data line 124 and the second selection line 132 on the substrate 100.

Each selection line includes the contact parts C, the first metal pattern layer M1 includes the scan lines, and the second metal pattern layer M2 includes the data lines and the selection lines. That is, the scan lines are made of the same material and are formed by the same process, and the data lines and the selection lines are made of the same material and are formed by the same process. In other words, the distance between the data lines and the surface of the substrate 100 is substantially equal to the selection lines and the surface of the substrate 100. In addition, in the normal direction of the substrate 100, the data lines and the selection lines are disposed on the scan lines. Taking FIG. 5 as an example, the second selection line 132 includes the contact parts C, the first metal pattern layer M1 includes the third scan line 113 and the fourth scan line 114, and the second metal pattern layer M2 includes the second data line 122A, the fourth data line 124 and the second selection line 132.

The contact parts C of each selection line pass through the insulating layer IL to electrically connect to the scan lines, and the contact parts C of each selection line are located at the intersections of the selection line and the scan lines. Taking FIG. 5 and FIG. 6 as an example. As shown in FIG. 6, the contact parts C of the second selection line 132 pass through the insulating layer IL to electrical connected to the third scan line 113 and the fourth scan line 114. As shown in FIG. 5, the contact parts C of the second selection line 132 are located at the intersections which the second selection line 132 intersects with the third scan line 113 and the fourth scan line 114. In some embodiments, the number of contact parts C of each selection line is at least two. In some embodiments, the contact parts C of each selection line pass through the insulating layer IL to contact the scan lines.

In summary, the present disclosure uses the connection design of the selection lines, the scanning lines and the active elements, so the scan signal provided by the driving circuit to a selection line can be transmitted to at least two scan lines via the selection line to control at least four active elements connected to the at least two scan lines, which allows sufficient charging time for the pixels to have a sufficient charging rate, and reduces the power consumption, as compared to the scan signals provided by the driving circuit to each of the scan lines individually. In addition, since the scan lines receives the scan signal from the driving circuit through the selection lines intersecting the scan lines, even if the number of scan lines is increased to twice the number of existing specification, the bezel width and pins of the existing specification chip do not need to be increased, so it can be applied to products with narrow bezels or products using the existing specification chips.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A display device, comprising:
an array substrate, comprising:
a substrate;
a plurality of scan lines, disposed on the substrate and comprising a first scan line, a second scan line and a third scan line, wherein the third scan line is disposed between the first scan line and the second scan line;
a plurality of data lines, disposed on the substrate and electrically insulated from the scan lines;
a plurality of selection lines, disposed on the substrate, intersecting with the scan lines and electrically insulated from the data lines, wherein the selection lines comprise a first selection line, the first selection line is electrically connected to the first scan line and the second scan line; and
a plurality of active elements, comprising a first active element, a second active element, a third active element and a fourth active element, wherein the first active element and the second active element are electrically connected to the first scan line, and the third active element and the fourth active element are electrically connected to the second scan line; and
a driving circuit, providing a plurality of data signals to the data lines and providing a plurality of scan signals to the selection lines, wherein the scan signals comprise a first scan signal transmitted to the first scan line and the second scan line through the first selection line to control the first active element, the second active element, the third active element and the fourth active element.

2. The display device of claim 1, wherein the scan lines further comprise a fourth scan line, the selection lines further comprise a second selection line, the active elements comprise a fifth active element, a sixth active element, a seventh active element and a eighth active element, and the scan signals comprise a second scan signal, wherein the second selection line is electrically connected to the third scan line and the fourth scan line, the fifth active element and the sixth active element are electrically connected to the third scan line, the seventh active element and the eighth active element are electrically connected to the fourth scan line, and the second scan signal is transmitted to the third scan line and the fourth scan line through the second selection line to control the fifth active element, the sixth active element, the seventh active element and the eighth active element.

3. The display device of claim 2, wherein the fourth scan line is disposed between the second scan line and the third scan line.

4. The display device of claim 1, wherein a number of the selection lines is not greater than half of a number of the scan lines.

5. The display device of claim 1, wherein each of the selection lines comprises a first line segment and a second line segment, the data lines and the second line segments are disposed on the scan lines and the first line segments in a normal direction of the substrate.

6. The display device of claim 5, wherein the array substrate further comprises an insulating layer disposed between the first line segments and the second line segments in the normal direction of the substrate, wherein each of the selection lines comprises a plurality of contact parts, the second line segment of each of the selection lines passes through the insulating layer at the contact parts of each of the selection lines to electrically connect to the first line segment of each of the selection lines, and the contact parts of each of the selection lines are not located at the intersection of the selection line and the scan lines.

7. The display device of claim 6, wherein a number of the contact parts of each of the selection lines is at least three.

8. The display device of claim 1, wherein the data lines and the selection lines are disposed on the scan lines in a normal direction of the substrate.

9. The display device of claim 8, wherein the array substrate further comprises an insulating layer disposed between the scan lines and the selection lines in the normal direction of the substrate, wherein each of the selection lines comprises a plurality of contact parts, the contact parts of each of the selection line pass through the insulating layer to electrically connect to the scan lines, and the contact parts of each of the selection lines are located at the intersections of the selection line and the scan lines.

10. The display device of claim 9, wherein a number of the contact parts of each of the selection lines is at least two.

11. An array substrate, comprising:
a substrate;
a plurality of scan lines, disposed on the substrate and comprising a first scan line, a second scan line and a third scan line, wherein the third scan line is disposed between the first scan line and the second scan line;
a plurality of data lines, disposed on the substrate and electrically insulated from the scan lines;
a plurality of selection lines, disposed on the substrate, intersecting with the scan lines and electrically insulated from the data lines, wherein the selection lines comprise a first selection line, the first selection line is electrically connected to the first scan line and the second scan line; and
a plurality of active elements, comprising a first active element, a second active element, a third active element and a fourth active element, wherein the first active element and the second active element are electrically connected to the first scan line, and the third active element and the fourth active element are electrically connected to the second scan line,
wherein the data lines receive a plurality of data signals and the selection lines receive a plurality of scan signals, and the scan signals comprise a first scan signal transmitted to the first scan line and the second scan line through the first selection line to control the first active element, the second active element, the third active element and the fourth active element.

12. The array substrate of claim 11, wherein the scan lines further comprise a fourth scan line, the selection lines further comprise a second selection line, the active elements comprise a fifth active element, a sixth active element, a seventh active element and a eighth active element, and the scan signals comprise a second scan signal, wherein the second selection line is electrically connected to the third scan line and the fourth scan line, the fifth active element and the sixth active element are electrically connected to the third scan line, the seventh active element and the eighth active element are electrically connected to the fourth scan line, and the second scan signal is transmitted to the third scan line and the fourth scan line through the second selection line to control the fifth active element, the sixth active element, the seventh active element and the eighth active element.

13. The array substrate of claim 12, wherein the fourth scan line is disposed between the second scan line and the third scan line.

14. The array substrate of claim 11, wherein a number of the selection lines is not greater than half of a number of the scan lines.

15. The array substrate of claim 11, wherein each of the selection lines comprises a first line segment and a second line segment, the data lines and the second line segments are disposed on the scan lines and the first line segments in a normal direction of the substrate.

16. The array substrate of claim 15, further comprising an insulating layer disposed between the first line segments and the second line segments in the normal direction of the substrate, wherein each of the selection lines comprises a plurality of contact parts, the second line segment of each of the selection lines passes through the insulating layer at the contact parts of each of the selection lines to electrically connect to the first line segment of each of the selection lines, and the contact parts of each of the selection lines are not located at the intersection of the selection line and the scan lines.

17. The array substrate of claim 16, wherein a number of the contact parts of each of the selection lines is at least three.

18. The array substrate of claim 11, wherein the data lines and the selection lines are disposed on the scan lines in a normal direction of the substrate.

19. The array substrate of claim 18, further comprising an insulating layer disposed between the scan lines and the selection lines in the normal direction of the substrate, wherein each of the selection lines comprises a plurality of contact parts, the contact parts of each of the selection line pass through the insulating layer to electrically connect to the scan lines, and the contact parts of each of the selection lines are located at the intersections of the selection line and the scan lines.

20. The array substrate of claim 19, wherein a number of the contact parts of each of the selection lines is at least two.
